(19) United States
(12) Patent Application Publication
(10) Pub. No.: US 2025/0132214 A1
(43) Pub. Date: Apr. 24, 2025

(54) SEMICONDUCTOR PACKAGE AND MANUFACTURING METHOD THEREOF

(71) Applicant: Taiwan Semiconductor Manufacturing Company, Ltd., Hsinchu (TW)

(72) Inventors: Hsien-Wei Chen, Hsinchu City (TW); Meng-Liang Lin, Hsinchu (TW); Ying-Ju Chen, Yunlin County (TW); Shin-Puu Jeng, Hsinchu (TW)

(73) Assignee: Taiwan Semiconductor Manufacturing Company, Ltd., Hsinchu (TW)

(21) Appl. No.: 18/489,853

(22) Filed: Oct. 19, 2023

(51) Int. Cl. H01L 23/31; H01L 21/56; H01L 23/00; H01L 23/29; H01L 23/367; H01L 23/48; H01L 23/538; H01L 25/00; H01L 25/10; H01L 25/18; H10B 80/00

(52) U.S. Cl. CPC H01L 23/3135; H01L 21/563; H01L 21/568; H01L 23/295; H01L 23/3121; H01L 23/5389; H01L 24/19; H01L 24/20; H01L 24/29; H01L 24/32; H01L 24/83; H01L 24/95; H01L 25/105; H01L 25/18; H01L 25/50; H10B 80/00; H01L 23/3675; H01L 23/481; H01L 24/13; H01L 24/16; H01L 24/30; H01L 24/33; H01L 24/73; H01L 24/81; H01L 24/92; H01L 2224/13124; H01L 2224/13139; H01L 2224/13144; H01L 2224/13147; H01L 2224/13155; H01L 2224/16227; H01L 2224/19; H01L 2224/214; H01L 2224/215; H01L 2224/221; H01L 2224/224; H01L 2224/29109; H01L 2224/29111; H01L 2224/29116; H01L 2224/29193; H01L 2224/2929; H01L 2224/29386; H01L 2224/30505; H01L 2224/32225; H01L 2224/32245; H01L 2224/3303; H01L 2224/33181; H01L 2224/33183; H01L 2224/73204; H01L 2224/73253; H01L 2224/81005; H01L 2224/81815; H01L 2224/83005; H01L 2224/83102; H01L 2224/83855; H01L 2224/92125; H01L 2224/92225; H01L 2224/95001; H01L 2225/1035; H01L 2225/1094; H01L 2924/01006; H01L 2924/01013; H01L 2924/01028; H01L 2924/01029; H01L 2924/01046; H01L 2924/01047; H01L 2924/0105; H01L 2924/01079; H01L 2924/014; H01L 2924/0503; H01L 2924/05432; H01L 2924/05442; H01L 2924/0635; H01L 2924/0665; H01L 2924/07025

(57) ABSTRACT

A semiconductor package includes a chiplet, a first underfill surrounding the chiplet, and a first encapsulant laterally covering the first underfill. The chiplet includes a semiconductor substrate and die connectors disposed over the semiconductor substrate. The first underfill includes first fillers, and a portion of the first fillers has a substantially planar surface at a first surface of the first underfill. The first encapsulant includes a first surface and a second surface opposite to the first surface, the first surface is substantially leveled with surfaces of the die connectors, and the second surface is substantially leveled with the first surface of the first underfill.

### BACKGROUND

Semiconductor devices and integrated circuits used in a variety of electronic applications are typically manufactured from a semiconductor wafer. The semiconductor dies of the semiconductor wafer are processed and packaged with other electronic devices at the wafer level, and various technologies have been developed for wafer level packaging. However, these relatively new types of packaging for semiconductors face manufacturing challenges. For example, when semiconductor dies are positioned on a carrier and a molding material is formed to cover the semiconductor dies, undesirable movement of the semiconductor dies occurs due to molding pressure applied to the semiconductor dies and may cause problems aligning subsequently formed materials of redistribution layer (RDL). Accordingly, such die dislocation in package formation results in reduced yields. Although existing semiconductor package and manufacturing method thereof have been generally adequate for their intended purposes, they have not been entirely satisfactory in all respects.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A and 1B illustrate schematic semiconductor dies (also called “chiplets”), in accordance with some embodiments.

FIGS. 2A through 2J illustrate schematic cross-sectional views of intermediate steps during a process for forming a semiconductor package, in accordance with some embodiments.

FIGS. 3A and 3B illustrate schematic top-down views of a semiconductor package, in accordance with some embodiments.

FIGS. 4A through 4C illustrate schematic cross-sectional views of intermediate steps during a process for forming a semiconductor package, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Embodiments will now be described with respect to particular structures and methods in which an underfill is utilized to prevent semiconductor dies shift out of their original position. The embodiments described herein are not intended to be limited to the embodiments described, and the embodiments may be implemented in any suitable structures and methods a chip on wafer on substrate (CoWoS) structure, a system on integrated circuit (SoIC) structure, or the like. All such embodiments are fully intended to be included within the scope of the embodiments.

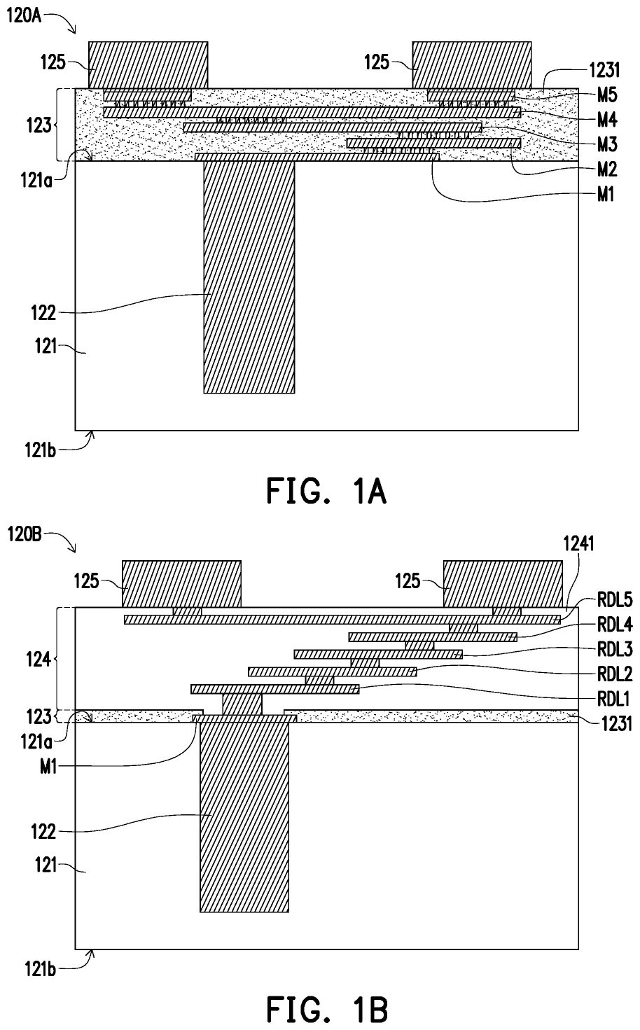

FIGS. 1A and 1B illustrate schematic semiconductor dies according to some embodiments. Referring to FIGS. 1A and 1B, first semiconductor dies (e.g., 120A, 120B) are provided. In some embodiments, the first semiconductor dies (120A and 120B) are referred to as chiplets. The first semiconductor dies (e.g., 120A, 120B) may be formed in the same wafer (or formed in the different wafers; not shown), and each wafer may include different die regions that are singulated to form a plurality of semiconductor dies (or chiplets). The first semiconductor dies 120A and 120B may be the same type of die having the same function (or same configuration). In some embodiments, the first semiconductor dies 120A and 120B are different types of dies having different functions (or different configurations).

In some embodiments, the respective first semiconductor die (e.g., 120A, 120B) includes a first semiconductor substrate 121, such as silicon, doped or undoped, or an active layer of a semiconductor-on-insulator (SOI) substrate. The first semiconductor substrate 121 may include other semiconductor materials, such as germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. Other substrate, such as multi-layered or gradient substrate, may be used. The first semiconductor substrate 121 includes a front side 121a and a back side 121b opposite to each other.

In some embodiments, the respective first semiconductor die (e.g., 120A, 120B) includes one or more through substrate vias (TSVs) 122 formed in the trenches of the first semiconductor substrate 121 by depositing one or more diffusion barrier layer(s) or isolation layer(s), depositing a seed layer, and depositing a conductive material (e.g., tungsten, titanium, aluminum, copper, any combinations thereof and/or the like) into the trenches of the first semiconductor substrate 121. For example, the respective TSV 122 has one end that is buried in the first semiconductor substrate 121 at this stage. In some embodiments, the respective first semiconductor die (e.g., 120A, 120B) includes one or more first die connectors 125 formed over the front side 121a and electrically coupled to the TSVs 122. The first die connectors 125 may be metallic pillars (e.g., copper pillars) formed by plating or the like. The respective first semiconductor die (e.g., 120A, 120B) may include active devices (e.g., transistors, diodes, or the like) and/or passive devices (e.g., capacitors, resistors, or the like) formed in/on the front side 121a of the first semiconductor substrate 121 and electrically coupled to the first die connectors 125. Alternatively, the first semiconductor die (120A and/or 120B) may be free of active/passive devices. The first semiconductor die (120A and/or 120B) may serve as a bridge die.

With reference to FIGS. 1A-1B, the first semiconductor dies 120A and 120B may be similar to each other. The difference therebetween includes that the first semiconductor die 120A has an interconnect structure 123 coupled to the first die connectors 125 and the TSVs 122, and the first semiconductor die 120A further includes a redistribution structure 124 interposed between the interconnect structure 123 and the first die connectors 125. For example, the interconnect structure 123 includes an interconnect dielectric layer 1231 and one or more interconnect patterns (e.g., M1, M2, M3, M4, M5) formed in the interconnect dielectric layer 1231. The interconnect dielectric layer 1231 may be inter-metallization dielectric (IMD) layers or may be formed of a low-K dielectric material, such as undoped silicate glass (USG), phosphosilicate glass (PSG), borophosphosilicate glass (BPSG), fluorosilicate glass (FSG), or the like. In some embodiments, the interconnect dielectric layer 1231 is a passivation film formed from a dielectric material silicon oxide, silicon nitride, the like, or combinations thereof. The interconnect patterns (e.g., M1, M2, M3, M4, M5) may be formed from a conductive material such as copper, aluminum, the like, or combinations thereof.

As shown in FIG. 1A, the first semiconductor die 120A includes the interconnect patterns (e.g., M1, M2, M3, M4, M5) which may route electrical signals by conductive vias. Each level of the interconnect patterns may include conductive lines and conductive pads. In some embodiments, the topmost interconnect pattern M5 is physically and electrically connected to the first die connectors 125 and the bottommost interconnect pattern M1 is physically and electrically connected to the TSVs 122. It should be noted that the number of interconnect patterns illustrated in FIGS. 1A and 1B is merely an example and construes no limitation in the disclosure.

As shown in FIG. 1B, the first semiconductor die 120B may include one layer of interconnect pattern M1 partially covered by the interconnect dielectric layer 1231. The redistribution structure 124 may include a dielectric layer 1241 formed on the interconnect dielectric layer 1231 and redistribution traces (e.g., RDL1, RDL2, RDL3, RDL4, RDL5) formed in the dielectric layer 1241. The material of the dielectric layer 1241 may be different from that of the interconnect dielectric layer 1231. For example, the dielectric layer 1241 includes one or more polymer materials such as polybenzoxazole (PBO), polyimide (PI), benzocyclobutene (BCB), or the like. The redistribution traces (e.g., RDL1, RDL2, RDL3, RDL4, RDL5) may include copper, alloy, or other suitable metal material, and each level may include conductive lines, conductive pads, and conductive vias vertically connecting the underlying level and the overlying level. The bottommost redistribution traces RDL1 may be physically and electrically connected to the interconnect pattern M1, and the topmost redistribution traces RDL5 may be physically and electrically connected to the first die connectors 125. In some embodiments, the line/spacing and the dimension of the respective redistribution trace are greater than those of the respective interconnect pattern. It should be noted that the above examples in FIGS. 1A and 1B are provided for illustrative purposes only, and the first semiconductor dies may utilize fewer or additional elements according to alternative embodiments.

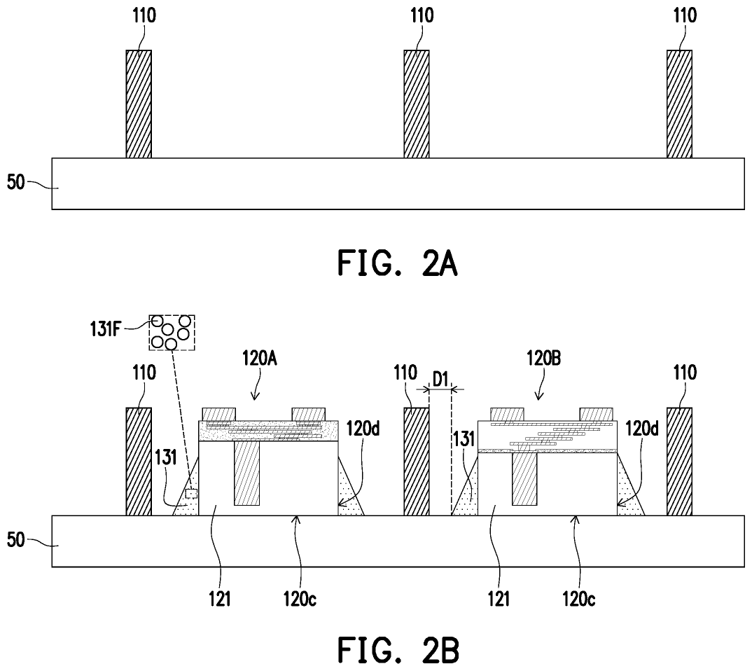

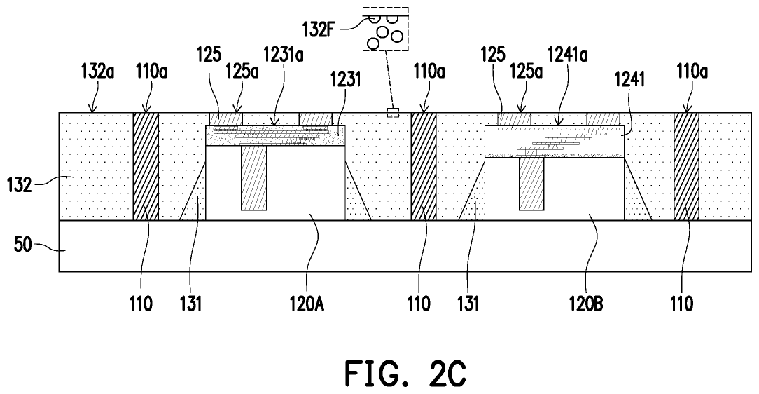

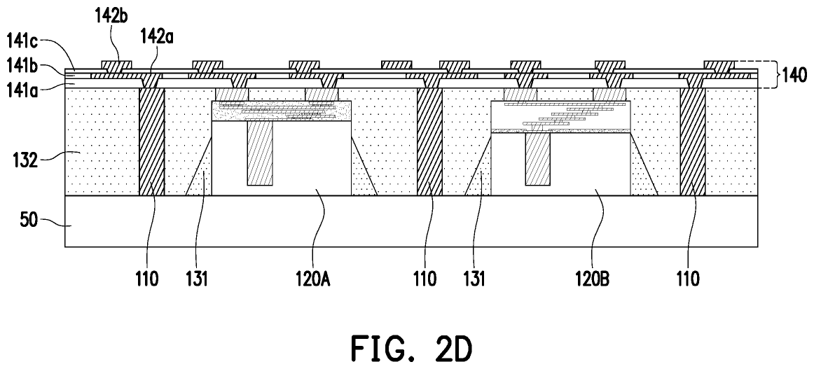

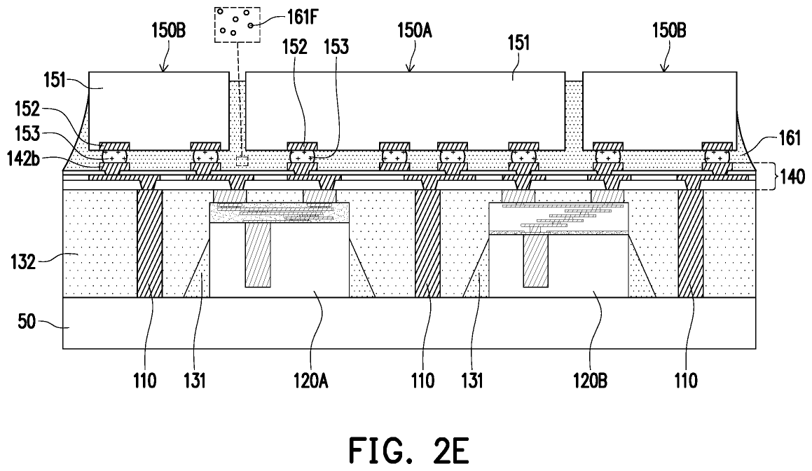

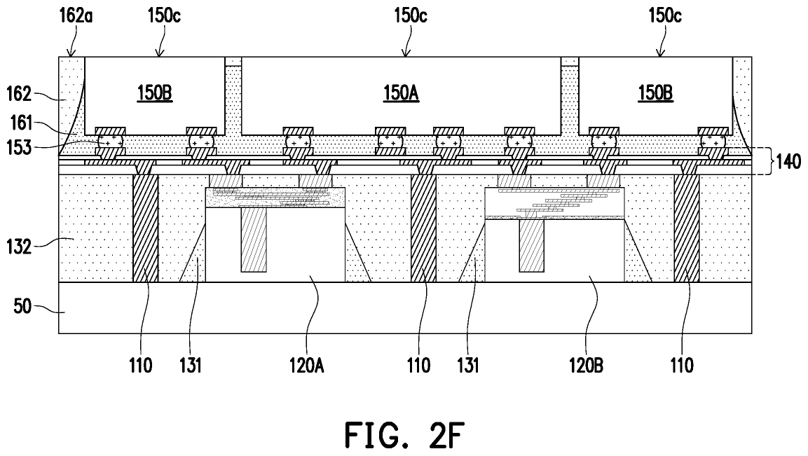

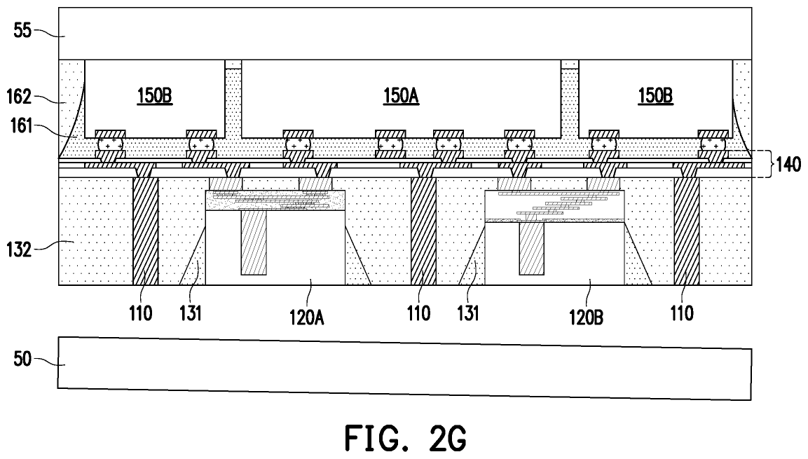

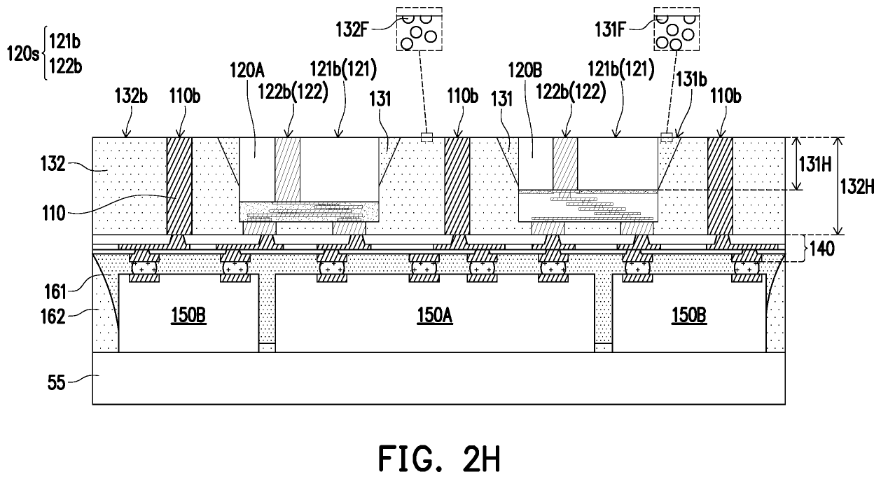

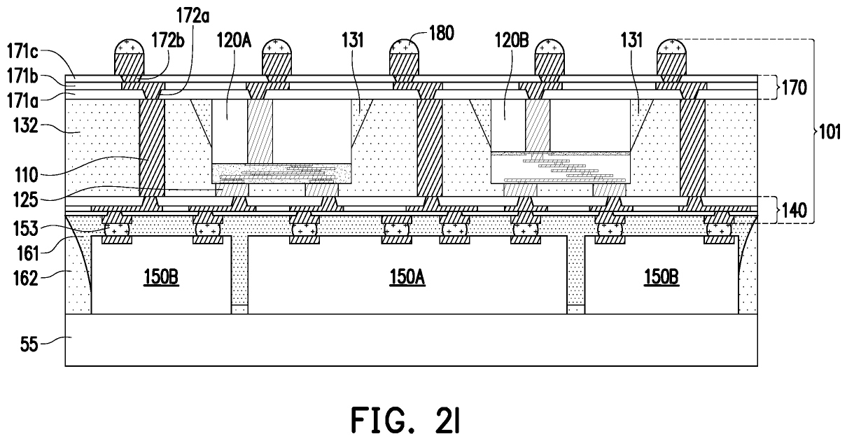

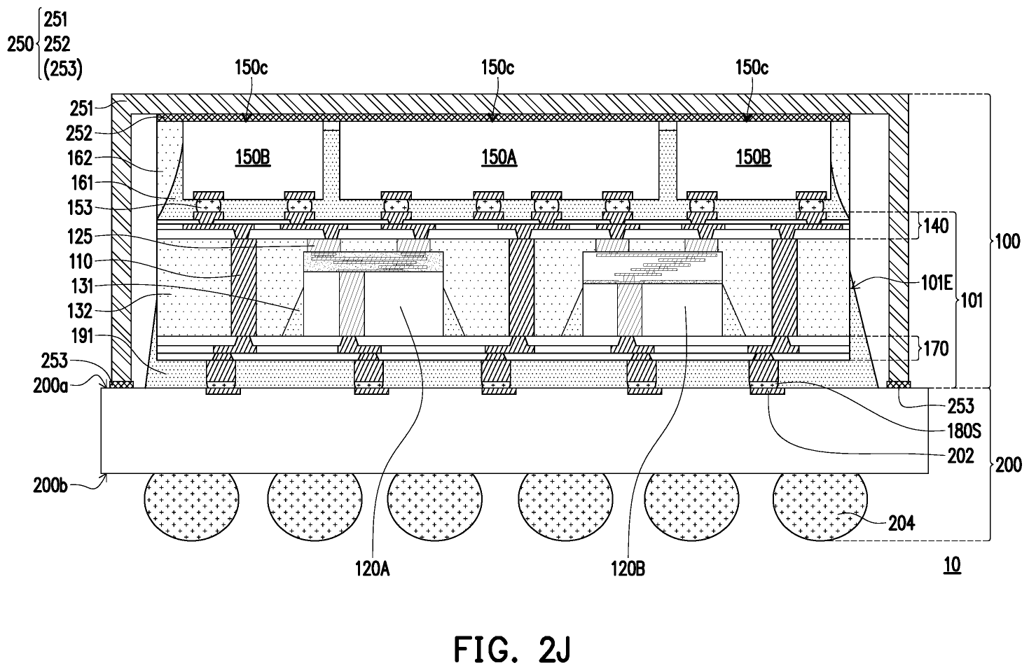

FIGS. 2A through 2J illustrate schematic cross-sectional views of intermediate steps during a process for forming a semiconductor package, in accordance with some embodiments. Unless specified otherwise, like reference numerals in the present embodiment represent like components in the embodiment shown in FIGS. 1A and 1B. Although method embodiments are discussed as being performed in a particular order, other embodiments may be performed in any logical order.

Referring to FIG. 2A, a first temporary carrier 50 is provided. For example, the first temporary carrier 50 includes silicon (e.g., bulk silicon), glass, metal (e.g., steel), ceramic, combinations thereof, multi-layers thereof, or the like. The first temporary carrier 50 may be provided in a wafer form, such that multiple device regions can be formed on the first temporary carrier 50 simultaneously. The process performed over the first temporary carrier 50 may be in wafer level. In some embodiments, a release layer (not shown) is formed on the first temporary carrier 50 to facilitate releasing the first temporary carrier 50 from the structure formed thereon in the subsequent process. For example, the release layer includes a layer of light-to-heat-conversion (LTHC) release coating and a layer of associated adhesive (e.g. ultra-violet curable adhesive or heat curable adhesive layer), or the like. Alternatively, the release layer is omitted.

In some embodiments, conductive pillars 110 are disposed over the first temporary carrier 50 (e.g., formed on the release layer, if present). As an example, to form the conductive pillars 110, a seed layer (not shown) is initially formed over the first temporary carrier 50. The seed layer may be a metal layer, which may be a single layer or a composite layer comprising sub-layers formed of different materials. In an embodiment, the seed layer includes a titanium layer and a copper layer over the titanium layer. A photoresist is formed and patterned on the seed layer. The photoresist may be formed by spin coating or the like and may be exposed to light for patterning. The pattern of the photoresist corresponds to conductive pillars. The patterning forms openings through the photoresist to expose the seed layer. A conductive material (e.g., copper, titanium, tungsten, aluminum, or the like) is formed in the openings of the photoresist and on the exposed portions of the seed layer by plating, such as electroplating or electroless plating, or the like. The photoresist and portions of the seed layer on which the conductive material is not formed are removed. The remaining portions of the seed layer and conductive material form the conductive pillars 110. In alternative embodiments, the conductive pillars 110 are pre-formed and placed over the first temporary carrier 50.

In some alternative embodiments, a backside redistribution structure (not separately illustrated) is first formed over the first temporary carrier 50, and then the conductive pillars 110 are formed on the back-side redistribution structure. The back-side redistribution structure includes any number of dielectric layers and metallization patterns (sometimes referred to as redistribution layers or redistribution lines) formed in the dielectric layers. The metallization patterns of the back-side redistribution structure may include conductive lines, conductive pads, and conductive vias, where the conductive vias in the back-side redistribution structure may be tapered toward the first temporary carrier 50. The conductive pillars 110 may be in physical and electrical contact with the topmost metallization pattern of the back-side redistribution structure.

Referring to FIG. 2B, one or more first semiconductor dies (e.g., 120A and/or 120B) may be picked and placed over the first temporary carrier 50. The first semiconductor dies (120A and 120B) are described in FIGS. 1A-1B, and thus the details are not repeated. The back side 120c of the respective first semiconductor die (e.g., 120A, 120B) may be disposed over the first temporary carrier 50 (e.g., the back side 120c is attached on the release layer, if the release layer is present). Although different types of first semiconductor dies 120A and 120B are placed over the first temporary carrier 50 as shown in FIG. 2B, a single type of the first semiconductor dies may be placed over the first temporary carrier 50 according to some embodiments. In some embodiments, the respective first semiconductor die (e.g., 120A, 120B) is surrounded by the conductive pillars 110.

In some embodiments, a first underfill 131 is formed over the first temporary carrier 50 to laterally surround the respective first semiconductor die (e.g., 120A, 120B) for protection. The first underfill 131 may be viewed as a protection layer. In some embodiments, the material of the first underfill 131 includes a polymer material and may include fillers 131F. The polymer material may be an epoxy, a polyimide-based material, an acrylic material, or the like. The fillers 131F may be formed of a material that provides mechanical strength (and/or thermal dispersion), such as silicon oxide, aluminum oxide, boron nitride, alumina, silica, or the like. In some embodiments, the material of the first underfill 131 is chosen such that the coefficient of thermal expansion (CTE) of the first underfill 131 is greater than the respective first semiconductor die (e.g., 120A, 120B). For example, the CTE of the first underfill 131 is between about 20 ppm/° C. and about 40 ppm/° C. The CTE of the first semiconductor die (e.g., 120A, 120B) is in a range of about 3 ppm/° C. and about 5 ppm/° C.

In some embodiments, an underfill material may be dispensed by a capillary flow process after the first semiconductor dies (120A and 120B) are placed over the first temporary carrier 50. A curing process (e.g., a thermal curing, a UV curing, the like, or a combination thereof) may be performed to cure the underfill material. In alternative embodiments, the underfill material is first formed over the first temporary carrier 50, and then the first semiconductor dies (120A and 120B) are picked and placed on the underfill material so that the back sides 120c of the first semiconductor dies (120A and 120B) may be covered by the underfill material. The heat (and/or pressure) may be applied to the underfill material to form the first underfill 131, and the first semiconductor dies (120A and 120B) may then be securely positioned in their predetermined locations over the first temporary carrier 50 through the first underfill 131.

In some embodiments, the first underfill 131 laterally surrounds the back side 120c of the respective first semiconductor die (e.g., 120A, 120B) and may climb up to partially (or fully) cover the sidewall 120d of the respective first semiconductor die (e.g., 120A, 120B) for protection. For example, the first underfill 131 covers at least the lower portion of the first semiconductor substrate 121. The thickness of the first underfill 131 on the sidewall 120d may gradually decrease from the back side 120c of the respective first semiconductor die (e.g., 120A, 120B) toward an upper portion of the sidewall 120d. In some embodiments, the boundary of the first underfill 131 is spatially separated from the closest one of the conductive pillars 110 by a distance D1. The distance D1 may (or may not) be non-zero.

Referring to FIG. 2C, a first encapsulant 132 may be formed over the first temporary carrier 50 to laterally cover the conductive pillars 110, the first underfill 131, and the first semiconductor dies (120A and 120B). In some embodiments, a first portion of the first encapsulant 132 is formed on the interconnect structure 123 of the first semiconductor die 120A to laterally cover the respective first die connector 125. For example, the first portion of the first encapsulant 132 is directly formed on a top surface 1231a of the interconnect dielectric layer 1231. In some embodiments, a second portion of the first encapsulant 132 is formed on the redistribution structure 124 of the first semiconductor die 120B to laterally cover the respective first die connector 125. For example, the second portion of the first encapsulant 132 is directly formed on a top surface 1241a of the dielectric layer 1241.

The material of the first encapsulant 132 may include molding compound, molding underfill, epoxy resin, phenolic resins, silicon-containing resins, or the like. The first encapsulant 132 may include fillers 132F. In some embodiments, the size of the fillers 132F is greater than (or substantially equal to) that of the fillers 131F included in the first underfill 131. The filler loading (density) of the fillers 132F included in the first encapsulant may be greater than (or substantially equal to that of the fillers 131F included in the first underfill 131. In some embodiments, the material of the first encapsulant 132 is chosen such that the CTE of the first encapsulant 132 is greater than the respective first semiconductor die (e.g., 120A, 120B). For example, the CTE of the first encapsulant 132 is between about 10 ppm/° C. and about 20 ppm/° C. The CTE of the first encapsulant 132 may be less than (or substantially equal to) the CTE of the first underfill 131. The first encapsulant 132 may be applied by compression molding, transfer molding, or the like. In some embodiments, the first encapsulant 132 is referred to as a first molding layer. The first encapsulant 132 may be applied in liquid or semi-liquid form and then subsequently cured.

In some embodiments, an encapsulating material is formed over the first temporary carrier 50 such that the conductive pillars 110, the first underfill 131, and the first semiconductor dies (120A and 120B) are buried or covered. A planarization process (e.g., chemical-mechanical polishing (CMP), grinding, etching, a combination thereof, etc.) is optionally performed on the encapsulating material to accessibly expose the conductive pillars 110 and the first die connectors 125 of the first semiconductor dies (120A and 120B). During the planarization process, some of the fillers 132F in the encapsulating material may be ground to have planar (rather than spherical) surfaces. In some embodiments, first surfaces 110a of the conductive pillars 110, surfaces 125a of the first die connectors 125, and a first surface 132a of the first encapsulant 132 are substantially leveled (e.g., coplanar) with one another after the planarization process, within process variations. Alternatively, the planarization is omitted, for example, if the conductive pillars 110 and/or the first die connectors 125 are already exposed. In some embodiments, the conductive pillars 110 penetrating through the first encapsulant 132 (e.g., the molding layer) may be referred to as through molding vias (TMVs) or through interlayer vias (TIVs).

Referring to FIG. 2D and with reference to FIG. 2C, a first redistribution structure 140 may be formed on the first encapsulant 132, the TMVs 110, and the first semiconductor dies (120A and 120B). In some embodiments, the first redistribution structure 140 includes one or more first dielectric layers (e.g., 141a, 141b, 141c) and one or more first conductive patterns (e.g., 142a, 142b) formed in/on the first dielectric layers (e.g., 141a, 141b, 141c) to be electrically coupled to the TMVs 110 and the first semiconductor dies (120A and 120B). The material(s) of the first dielectric layers (e.g., 141a, 141b, 141c) may include electrically insulating polymer materials such as PBO, PI, BCB, a combination thereof, or the like. The first conductive patterns (e.g., 142a, 142b) may include conductive vias, conductive pads, and conductive lines which are collectively referred to as redistribution lines. The first conductive patterns (e.g., 142a, 142b) may be formed from conductive material(s) such as solder, copper, aluminum, gold, nickel, silver, palladium, tin, alloy, the like, a combination thereof, etc.

In some embodiments, the bottommost one 141a of the first dielectric layers is directly formed on the first surface 132a of the first encapsulant 132 and partially covers the first surfaces 110a of the TMVs 110 and the surfaces 125a of the first die connectors 125. The conductive vias of the bottommost one 142a of the first conductive patterns may be formed in the bottommost one 141a of the first dielectric layers and land on the first surfaces 110a of the TMVs 110 and the surfaces 125a of the first die connectors 125. The topmost one 142b of the first conductive patterns may include the conductive pads (e.g., under bump metallization (UBM) pads) formed on the topmost one 141c of the first dielectric layers. Solder bumps (not shown) are optionally formed on the UBM pads for the subsequently-performed die attachment (see FIG. 2E). It should be noted that although three layers of the first dielectric layers and two layers of the first conductive patterns are illustrated, the numbers of the first dielectric layers and the first conductive patterns may be selected based on demand and are not limited in the disclosure.

Referring to FIG. 2E and with reference to FIG. 2D, one or more second semiconductor dies (e.g., 150A, 150B) may be disposed on the first redistribution structure 140. The second semiconductor dies (e.g., 150A, 150B) may be electrically coupled to the TMVs 110 and the first semiconductor dies (120A and 120B) through the first conductive patterns (142a and 142b) of the first redistribution structure 140. The respective second semiconductor die (e.g., 150A, 150B) may be or include a logic die (e.g., central processing unit (CPU), graphics processing unit (GPU), system-on-a-chip (SoC), application processor (AP), microcontroller, etc.), a memory die (e.g., high bandwidth memory (HBM) die, hybrid memory cube (HMC) die, dynamic random access memory (DRAM) die, static random access memory (SRAM) die, etc.), a power management die (e.g., power management integrated circuit (PMIC) die), a radio frequency (RF) die, a sensor die, a micro-electro-mechanical-system (MEMS) die, a signal processing die (e.g., digital signal processing (DSP) die), a front-end die (e.g., analog front-end (AFE) dies), a voltage regulator die, a combination thereof, and/or the like.

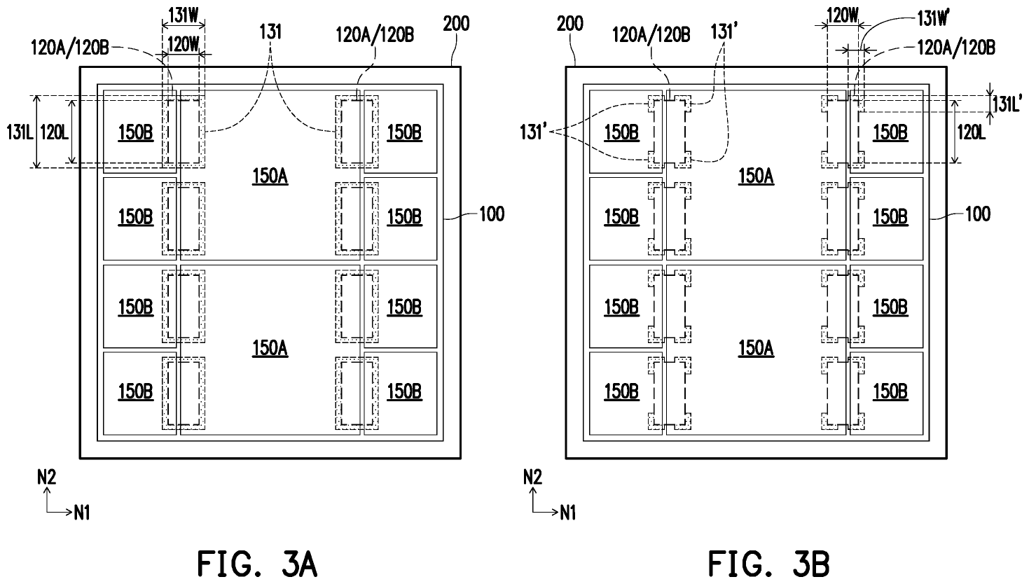

The second semiconductor dies (150A and 150B) may be the same type of die or may be different types of dies. In an embodiment, the second semiconductor die 150A is a logic die (e.g., SoC die) and the second semiconductor dies 150B are memory dies (e.g., HBM dies) surrounding the logic die. The respective first semiconductor die (e.g., 120A or 120B) may partially overlap the second semiconductor die 150A and at least one of the second semiconductor die 150B, in a top-down view. The first semiconductor dies (e.g., 120A, 120B) may function to provide electrical communication between two or more second semiconductor dies (e.g., 150A, 150B). The details of the top-view configuration will be described in accompanying with FIGS. 3A-3B.

In some embodiments, the respective second semiconductor die (e.g., 150A, 150B) includes a second semiconductor substrate 151 and second die connectors 152 disposed over the second semiconductor substrate 151. In some embodiments, the second die connectors 152 are coupled to the topmost one 142b of the first conductive patterns (e.g., conductive pads or UBM pads) through first conductive joints 153. The first conductive joints 153 may be formed from conductive materials such as solder, copper, aluminum, gold, nickel, silver, the like, or a combination thereof. In some embodiments, the first conductive joints 153 are solder joints that are formed by forming solder material on the topmost one 142b of the first conductive patterns, and then reflowing the solder material to enhance the adhesion between the second semiconductor dies (e.g., 150A, 150B) and the first redistribution structure 140.

With continued reference to FIG. 2E, a second underfill 161 may be formed in a gap between the first redistribution structure 140 and the second semiconductor dies (e.g., 150A, 150B) to surround the first conductive joints 153. In some embodiments, the second underfill 161 continuously extends between adjacent two of the second semiconductor dies (e.g., 150A-150B or 150B-150B). Alternatively, the second underfill 161 includes discrete portions, and each portion of the second underfill 161 surround one of the second semiconductor dies (e.g., 150A, 150B). In some embodiments, the second underfill 161 covers the conductive pads of the topmost one 142b of the first conductive patterns underlying the first conductive joints 153. The second underfill 161 may be formed by a capillary flow process after the second semiconductor dies (e.g., 150A, 150B) are attached or may be formed by a suitable deposition method before the second semiconductor dies (e.g., 150A, 150B) are attached. A curing process may be performed to solidity the underfill material so as to form the second underfill 161.

In some embodiments, the material of the second underfill 161 includes a polymer material and may include fillers 161F. The polymer material may be an epoxy, a polyimide-based material, an acrylic material, or the like. The fillers 161F may include silicon oxide, aluminum oxide, boron nitride, alumina, silica, or the like. The filler size and filler loading (density) of the second underfill 161 may be different from those of the first underfill 131, such that the first underfill 131 has different physical properties (e.g. CTE, Young's modulus, viscosity, etc.) than the second underfill 161. The sizes and the content of the fillers 161F may be controlled within a suitable range, such that the second underfill 161 may extend into the gap between the second semiconductor dies (150A and 150B) and the first redistribution structure 140. In some embodiments, the size of the fillers 131F (see in FIG. 2B) included in the first underfill 131 is greater than the size of the fillers 161F included in the second underfill 161. The filler loading of the first underfill 131 may be greater than that of the second underfill 161. For example, the filler loading of the first underfill 131 is in a range of about 60% and about 90%, and the filler loading of the second underfill 161 is in a range of about 40% and about 60%. The CTE of the second underfill 161 may be greater than the CTE of the first underfill 131. Compared to the first underfill 131, the second underfill 161 may have the high fluidity and the low viscosity, since the reciprocal of viscosity is fluidity. The second underfill 161 having high fluidity may facilitate filling in the gap among the second semiconductor dies (e.g., 150A and 150B), the first redistribution structure 140, and the first conductive joints 153. Alternatively, the second underfill 161 is omitted.

Referring to FIG. 2F and with reference to FIG. 2E, a second encapsulant 162 may be formed on the first redistribution structure 140 to at least laterally cover the second semiconductor dies (e.g., 150A and 150B) and the second underfill 161. The material and the forming process of the second encapsulant 162 may be similar to those of the first encapsulant 132 described in FIG. 2C, and thus the detailed descriptions of the second encapsulant 162 are not repeated herein. In some embodiments, the second encapsulant 162 is referred to as a second molding layer. In some embodiments where the second underfill 161 is omitted, the second encapsulant 162 may be molding underfill which fills the space that is filled by the second underfill 161. The back side 150c of the respective second semiconductor die (150A and/or 150B) may be accessibly exposed by the second encapsulant 162. For example, the planarization process is performed to level the surface 162a of the second encapsulant 162 and the back side 150c of the respective second semiconductor die (150A and/or 150B). Alternatively, the back side 150c of the second semiconductor die (150A and/or 150B) is covered by the second encapsulant 162.

Referring to FIG. 2G and with reference to FIG. 2F, the first temporary carrier 50 may be de-bonded from the overlying structure. In some embodiments where the first temporary carrier 50 is provided with the LTHC layer, the de-bonding of the first temporary carrier 50 includes projecting a light (e.g., laser light or UV light) on the release layer (if present), so that the release layer decomposes under the heat of the light and the first temporary carrier 50 and the release layer are removed. In some embodiments where the first temporary carrier 50 is provided with an adhesive layer, a suitable solvent may be used to dissolve the adhesive layer. In some embodiments, the first temporary carrier 50 is removed through stripping, peeling, etching, a combination thereof, etc. After the first temporary carrier 50 is removed, the first encapsulant 132, the TMVs 110, the first underfill 131, and the first semiconductor dies (120A and 120B) may be accessibly exposed.

In some embodiments, a second temporary carrier 55 is attached to the second encapsulant 162 and the second semiconductor die (150A and/or 150B) (if the back side 150c is exposed by the second encapsulant 162). In some embodiments, the second temporary carrier 55 is provided with a release layer (not shown) to facilitate releasing the second temporary carrier 55 from the resulting structure in the subsequent process. Alternatively, the release layer is omitted.

Referring to FIG. 2H and with reference to FIG. 2G, the structure of FIG. 2G may be flipped over for further processing. For example, a planarization process (e.g., CMP, grinding, etching, a combination thereof, etc.) is performed to accessibly expose the TSVs 122 of the first semiconductor dies (120A and 120B). During the planarization process, the first semiconductor substrate 121 is thinned down until the surfaces 122b of the TSVs are accessibly exposed. During the planarization process, some of the fillers 132F in the first encapsulant 132 and some of the fillers 131F in the first underfill 131 may be ground to have planar (rather than spherical) surfaces, as shown in the enlarged views. In some embodiments, second surfaces 110b of the TMVs 110, the rear surfaces 120s of the first semiconductor dies (120A and 120B), the surface 131b of the first underfill 131, and a second surface 132a of the first encapsulant 132 are substantially leveled (e.g., coplanar) with one another after the planarization process, within process variations. In some embodiments, the maximum height (or the thickness) 132H of the first encapsulant 132 is greater than the maximum height 131H of the first underfill 131H. For example, a ratio of the maximum height 131H to the maximum height 132H is greater than (or substantially equal to) about 0.2 and may be less than (or substantially equal to) 1. The maximum height 131H of the first underfill 131H may range from about 50 μm to about 1000 μm, inclusive. Although other values may be possible depending on the process and product requirements.

Referring to FIG. 2I and with reference to FIG. 2H, a second redistribution structure 170 may be formed on the first encapsulant 132, the TMVs 110, the first encapsulant 131, and the first semiconductor dies (120A and 120B). In some embodiments, the second redistribution structure 170 includes one or more first dielectric layers (e.g., 171a, 171b, 171c) and one or more second conductive patterns (e.g., 172a, 172b) formed in/on the second dielectric layers (e.g., 171a, 171b, 171c) to be electrically coupled to the TMVs 110 and the first semiconductor dies (120A and 120B). The material(s) of the second dielectric layers (e.g., 171a, 171b, 141c) may be similar to that of the first dielectric layers of the first redistribution structure 140, and the material(s) of the second conductive patterns (e.g., 172a, 172b) may be similar to that of the first conductive patterns of the first redistribution structure 140. The second conductive patterns (e.g., 172a, 172b) may include conductive vias, conductive pads, and conductive lines which are collectively referred to as redistribution lines. In some embodiments, the first redistribution structure 140 connected to the die connectors of the first and second semiconductor dies is referred to as a front side redistribution structure, and the second redistribution structure 170 connected to the back sides of the first semiconductor dies is referred to as a backside redistribution structure.

In some embodiments, the bottommost one 171a of the second dielectric layers is directly formed on the second surface 132b of the first encapsulant 132 and the surface 131b of the first underfill 131, the second surfaces 110b of the TMVs 110, and the back sides 120c of the first semiconductor dies (120A and 120B). The bottommost one 171a of the second dielectric layers may have openings to accessibly expose at least a portion of the TMVs 110 and the TSVs 122. The conductive vias of the bottommost one 172a of the second conductive patterns may be formed in the openings of the bottommost one 171a of the second dielectric layers and land on the TMVs 110 and the TSVs 122. The conductive vias in the second redistribution structure 170 may be tapered in a direction toward the TMVs 110 and the die connectors 125, and the tapering direction of the conductive vias in the second redistribution structure 170 is opposite to a tapering direction of the conductive vias in the first redistribution structure 140. It should be noted that although three layers of the second dielectric layers and two layers of the second conductive patterns are illustrated, the numbers of the second dielectric layers and the second conductive patterns may be selected based on demand and are not limited in the disclosure.

With continued reference to FIG. 2I, conductive terminals 180 may be formed on the topmost one 172b of the second conductive patterns of the second redistribution structure 170. The conductive terminals 180 may include conductive material(s) such as solder, copper, aluminum, gold, nickel, silver, palladium, tin, alloy, the like, or a combination thereof. For example, the respective conductive terminal 180 includes a pillar portion (e.g., copper pillar) and a cap portion (e.g., solder cap) formed on the pillar portion. In some embodiments, the conductive terminals 180 are controlled collapse chip connection (C4) bumps. In some embodiments, the conductive terminals 180 may be ball grid array (BGA) connectors, solder balls, metal pillars, micro-bumps, electroless nickel-electroless palladium-immersion gold (ENEPIG) bumps, or the like. In some embodiments, the upper structure (e.g., the first redistribution structure 140, the first encapsulant 132, the first underfill 131, the TMVs 110, the first semiconductor dies (120A and 120B), the second redistribution structure 170, and the conductive terminals 180) is collectively viewed as an interposer 101 (or referred to as an organic interposer).

Referring to FIG. 2J and with reference to FIG. 2I, the second temporary carrier 55 may be de-bonded from the overlying structure. The de-bonding of the second temporary carrier 55 may be similar to the removal process of the first temporary carrier 50 described in FIG. 2G. In some embodiments, the resulting structure formed in wafer level may be flipped over and placed on a dicing tape (not shown), and then a singulation process may be performed to divide the resulting structure into individual first package components 100. The first package component 100 may be disposed on and electrically coupled to a second package component 200 through second conductive joints 180S.

The second package component 200 may be or include a package substrate (e.g., a printed circuit board (PCB), an organic substrate, a ceramic substrate, etc.), a circuit substrate, a motherboard, and/or the like. The second package component 200 may be used to interconnect the first package component 100 with other packages/devices to form functional circuits. The second package component 200 has a first side 200a bonded to the first package component 100 and a second side 200b opposite to the first side 200a. In some embodiments, the second package component 200 includes external terminals 204 formed on the second side 200b. For example, the external terminals 204 are BGA connectors. In some embodiments, the external terminals 204 includes solder balls, metal pillars, C4 bumps, micro bumps, ENEPIG formed bumps, or the like.

In some embodiments, the second package component 200 includes contact pads 202 formed on the first side 200a, and the conductive terminals 180 may be disposed on the contact pads 202. A reflow process may be performed on the conductive terminals 180, and the solder portions of the conductive terminals 180 may be connected to the contact pads 202 so as to form the second conductive joints 180S (e.g., solder joints). In some embodiments, the second conductive joints 180S includes C4 bumps, solder balls, metal pillars, micro bumps, ENEPIG formed bumps, or the like. The dimension of the respective second conductive joint 180S may be greater than that of the respective first conductive joint 153. The dimension of the respective external terminal 204 may be greater than that of the respective second conductive joint 180S.

In some embodiments, a third underfill 191 is formed in a gap between the first side 200a of the second package component 200 and the second redistribution structure 170 to surround the second conductive joints 180S. In some embodiments, the third underfill 191 extends upward to cover at least a lower portion of the edge 101E of the interposer 101. Alternatively, the third underfill 191 is omitted. The material and the forming process of the third underfill 191 may be similar to those of the second underfill 161. The first package component 100 and the second package component 200 may be collectively viewed as a semiconductor package 10. In some embodiments, the semiconductor package 10 is referred to as a three-dimensional integrated circuit (3DIC) package or a chip-on-wafer-on-substrate (CoWoS) package.

A heat dissipation component 250 is optionally attached to and thermally coupled to the first package component 100. For example, the heat dissipation component 250 includes a lid 251 and an interface layer 252 interposed between and thermally coupled to the lid 251 and the first package component 100. In some embodiments, the interface layer 251 is in physical and thermal contact with the back side 150c of the respective second semiconductor die (150A and/or 150B). The interface layer 252 may be a pre-formed film which is highly compressible, has a high adhesion, and has a high thermal conductivity. For example, the interface layer is a material such as lead-tin based solder, lead-free solder, indium, carbon composite materials, graphite, carbon nanotubes, or other suitable thermally conductive materials. The interface layer 252 includes a thermal interface material. The lid 251 may include copper, aluminum, other metals, alloys, combinations thereof, or other material of high electrical and thermal conductivities. The lid 251 may be mounted on the periphery of the second package component 200 through an adhesive layer 253. For example, the lid 251 is sealed using a heat clamping method, wherein pressure and heat are applied in order to seal the lid 251 to the CoWoS package. However, any suitable method of sealing the lid 251 may be utilized. In some embodiments, the adhesive layer 253 including thermally conductive material(s) may be viewed as a part of the heat dissipation component 250. In alternative embodiments, the lid 251 is replaced with a heat sink (or heat spreader) which is only attached onto the first package component 100 without mounted onto the second package component 200.

As shown in FIG. 2J, the semiconductor package 10 include the interposer 101 coupling the overlying second semiconductor dies (150A and 150B) to the underlying second package component 200. The second semiconductor dies (150A and 150B) may include at least one SoC die integrated with HBM dies. The SoC die and the HBM dies may be disposed on and coupled to the interposer 101 to minimize ohmic losses and RC delay. The interposer 101 may include one or more chiplets (e.g., the first semiconductor dies 120A and/or 120B) packaged together. The chiplets may implement and electrically communicate with the various functional blocks of the SoC die. The first semiconductor dies (120A and 120B) may be secured by the first underfill 131 and encapsulated by the first encapsulant 132.

It is appreciated that having proper alignment between the first die connectors 125 of the first semiconductor dies (120A and 120B) and the first conductive patterns of the first redistribution structure 140 is very important for the fabrication of the semiconductor package 10. Improper alignment may result from various reasons during fabrication. For example, when curing the encapsulating material to form the first encapsulant 132, the encapsulating material deforms, and non-uniform stress may be applied to the first semiconductor dies (120A and 120B) to cause the first semiconductor dies (120A and 120B) shift out of their original positions. If the first semiconductor dies (120A and 120B) shift from one manufacturing process to a subsequent manufacturing process, patterns in the upper layer become misaligned to patterns in the lower layer. Such misalignment may lead to undesired electrical shorting in the interposer 101 and cold joints on the first conductive joints 153 because of misalignment of subsequent lithography process for forming the first redistribution structure 140 with respect to the shifted first semiconductor dies. By configuring the first underfill 131, the first semiconductor dies (120A and 120B) may be secured in place for the duration of the process (e.g., the formation of the first encapsulant 132). The misalignment and cold joint issues may be eliminated, thereby improving the reliability of the semiconductor package 10.

FIGS. 3A and 3B illustrate schematic top-down views of a semiconductor package, in accordance with some embodiments. Unless specified otherwise, like reference numerals in this embodiment represent like components in the embodiment shown in FIGS. 2A-2J. It should be noted that FIGS. 3A and 3B are simplified and may not depict all of the components of the semiconductor package 10. Specifically, FIGS. 3A and 3B shows the boundaries of the second package component 200 and the first package component 100; FIGS. 3A and 3B also shows the configuration of the second semiconductor dies (150A and 150B) and the configuration of the first semiconductor dies (120A and 120B) and the first underfill 131. Besides these components, the rest components in the semiconductor package 10 are not shown for the sake of clarity.

Referring to FIG. 3A and with reference to FIG. 2J, in the top view, the boundary of the first package component 100 is entirely located within that of the second package component 200. The boundary of the first package component 100 may include sidewalls (or edges) of the first and second encapsulants (132 and 162) and the first and second redistribution structures (140 and 170). The first and second semiconductor dies may be located within the boundary of the first package component 100. In some embodiments, one type of the second semiconductor dies 150A are disposed side-by-side, while another type of the second semiconductor dies 150B are disposed alongside the second semiconductor dies 150A. The respective first semiconductor die (120A or 120B) may be disposed directly below the adjacent two of the second semiconductor dies (150A and 150B) and overlap the adjacent two of the second semiconductor dies (150A and 150B) in the top view. It should be noted that other configuration of the first and second semiconductor dies is possible and fully intended to be included within the scope of the embodiments.

In some embodiments, the boundary of the respective first semiconductor die (120A or 120B) is fully located within the boundary of the corresponding first underfill 131. The first underfill 131 may continuously surround each side of the respective first semiconductor die (120A or 120B) in the top view. The first underfill 131 may include a first lateral dimension (e.g., a maximum width) 131 W in a first direction N1 that is greater than a first lateral dimension (e.g., a maximum width) 120 W of the corresponding first semiconductor die (120A or 120B). For example, the first lateral dimension 131W ranges from about 50 μm to about 1000 μm, inclusive. The first underfill 131 may include a second lateral dimension 131L (e.g., a maximum length) in a second direction N2 that is greater than a second lateral dimension (e.g., a maximum length) 120 L of the corresponding first semiconductor die (120A or 120B). The first direction N1 may be substantially perpendicular to the second direction N2. The second lateral dimension 131L ranges from about 50 μm to about 1000 μm, inclusive.

Referring to FIG. 3B and with reference to FIG. 3A, the configuration shown in FIG. 3B is similar to the configuration shown in FIG. 3A, except that the first underfill illustrated in FIG. 3B is formed as a plurality of discrete portions 131′. In some embodiments, each discrete portion 131′ surrounds one of the corners of the corresponding first semiconductor die (120A or 120B). The discrete portions 131′ may each be surrounded by the first encapsulant 132 and separated from each other by the first encapsulant 132. The first underfill 131′ may include a first lateral dimension (e.g., a maximum width) 131 W′ in the first direction N1 that is less than the first lateral dimension 120W of the corresponding first semiconductor die (120A or 120B). For example, the first lateral dimension 131W′ ranges from about 50 μm to about 1000 μm, inclusive. The first underfill 131′ may include a second lateral dimension 131L (e.g., a maximum length) in the second direction N2 that is less than the second lateral dimension 120L of the corresponding first semiconductor die (120A or 120B). The second lateral dimension 131L ranges from about 50 μm to about 1000 μm, inclusive. In alternative embodiments, two adjacent portions 131′ are connected in the top view. For example, the first lateral dimension of the first underfill is greater than the first lateral dimension of the first semiconductor die, while the second lateral dimension of the first underfill is less than the second lateral dimension of the first semiconductor die. It should be noted that some of the first underfill 131W′ may be replaced with the first underfill 131W shown in FIG. 3A.

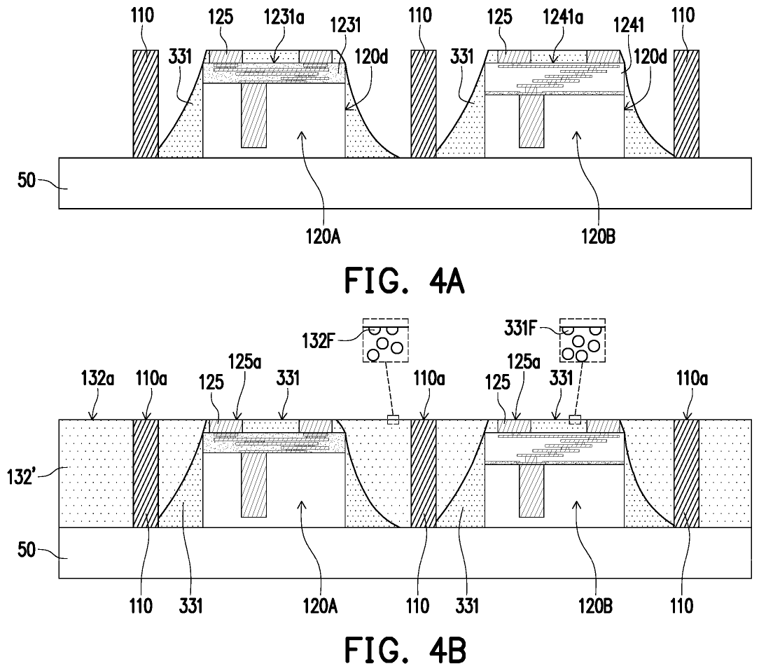

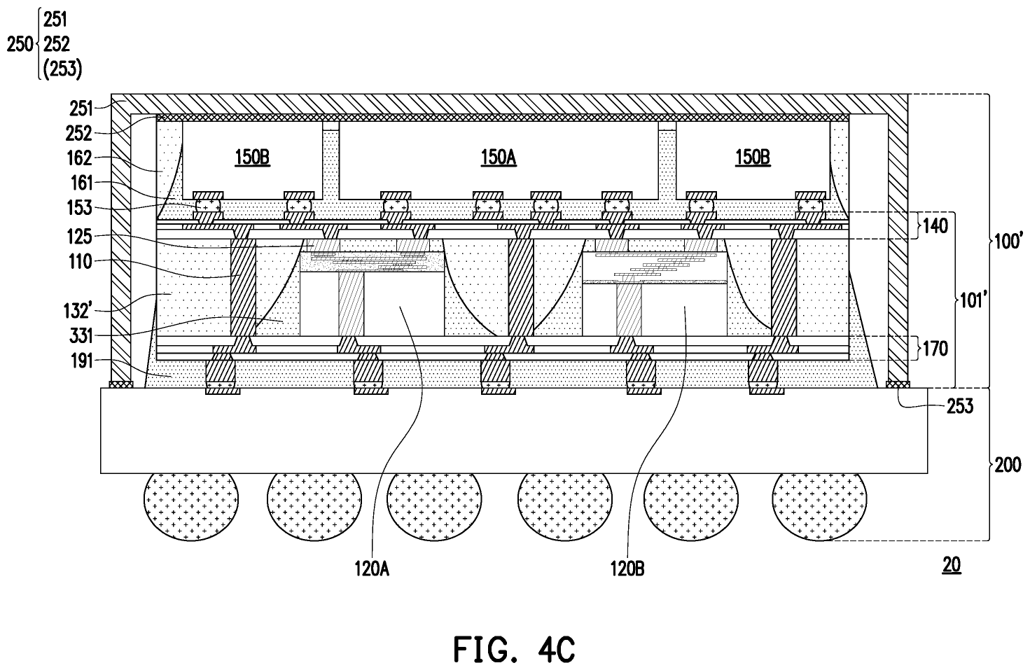

FIGS. 4A through 4C illustrate schematic cross-sectional views of intermediate steps during a process for forming a semiconductor package, in accordance with some embodiments. Unless specified otherwise, like reference numerals in this embodiment represent like components in the embodiment shown in FIGS. 2A through 2J formed by like processes, and only differences will be the focus of the following discussion. Accordingly, the processes and applicable materials may not be repeated herein.

Referring to FIG. 4A and with reference to FIG. 2B, the structure illustrated in FIG. 4A is similar to the structure illustrated in FIG. 2B, except that the first underfill 331 extends further to be in contact with the conductive pillars 110. Depending on the applied amount of the underfill material, the first underfill 331 may fully (or partially) cover the entirety of the sidewall 120d of the first semiconductor die (120A and/or 120B). The first underfill 331 may extend further to cover the top surface 1231a of the interconnect dielectric layer 1231 of the first semiconductor die 120A and/or the top surface 1241a of the dielectric layer 1241 of the first semiconductor die 120B. In some embodiments, the first die connectors 125 of the first semiconductor dies (120A and/or 120B) are laterally covered by the first underfill 331. In some embodiments, the first die connectors 125 are buried in the first underfill 331 at this stage.

Referring to FIG. 4B and with reference to FIG. 4A and FIG. 2C, the first encapsulant 132′ may be formed over the first temporary carrier 50 to laterally cover the conductive pillars 110 and the first underfill 331. The material and the forming process of the first encapsulant 132′ may be similar to those of the first encapsulant 132 described in FIG. 2C. The structure illustrated in FIG. 4B is similar to the structure illustrated in FIG. 2C, except the profile of the first underfill 331. For example, the respective conductive pillar 110 has a portion covered by the first underfill 331 and the other portion covered by the first encapsulant 132′. The first semiconductor die (120A and/or 120B) may be separated from the first encapsulant 132′ by the first underfill 331. In some embodiments, the planarization process is performed to ensure the die connectors 125 are accessibly exposed by the first encapsulant 132′ and the first underfill 331. In some embodiments, the planarization process causes some of the fillers 132F in the first encapsulant 132′ and some of the fillers 331F in the first underfill 331 to be grounded to have planar (rather than spherical) surfaces, as shown in the enlarged views. For example, the first surfaces 110a of the conductive pillars 110, the surfaces 125a of the first die connectors 125, the first surface 132a of the first encapsulant 132′, and the first surface 331a of the first underfill 331 are substantially leveled (e.g., coplanar) with one another, within process variations.

Referring to FIG. 4C and with reference to FIG. 4B and FIG. 2J, after forming the first encapsulant 132′, the subsequent processes performed on the structure shown in FIG. 4B may be similar to the processes described in FIGS. 2D-2J so as to form a semiconductor package 20. The semiconductor package 20 is similar to the semiconductor package 10 shown in FIG. 2J, except for the profiles of the first underfill 331 and the first encapsulant 132′. The details thereof are described in the preceding paragraphs and not repeated for the sake of brevity.

By utilizing the materials and processes presented herein, the first underfill provides for a better overall structure and process. In addition, by configuring the first underfill to surround the first semiconductor dies before the formation of the first encapsulant, the issue caused by the die shift may be reduced or eliminated, further providing opportunities for package design flexibility and yield improvement.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

According to some embodiments, a semiconductor package includes a chiplet, a first underfill surrounding the chiplet, and a first encapsulant laterally covering the first underfill. The chiplet includes a semiconductor substrate and die connectors disposed over the semiconductor substrate. The first underfill includes first fillers, and a portion of the first fillers has a substantially planar surface at a first surface of the first underfill. The first encapsulant includes a first surface and a second surface opposite to the first surface, the first surface is substantially leveled with surfaces of the die connectors, and the second surface is substantially leveled with the first surface of the first underfill.

According to some alternative embodiments, a semiconductor package includes an interposer and semiconductor dies disposed on the interposer. The interposer includes a chiplet, a first underfill covering at least a portion of a sidewall of the chiplet, and an encapsulant covering the first underfill. The semiconductor dies are electrically coupled to the chiplet. The chiplet includes a semiconductor substrate, a TSV penetrating through the semiconductor substrate, and die connectors disposed over the semiconductor substrate and electrically coupled to the TSV. A coefficient of thermal expansion of the first underfill being greater than that of the encapsulant.

According to some alternative embodiments, a manufacturing method of a semiconductor package includes forming an interposer and coupling semiconductor dies to the interposer. Forming the interposer includes: securing a chiplet to a temporary carrier by using a first underfill; forming an encapsulant over the temporary carrier to laterally cover the first underfill and the chiplet; and planarizing a backside of the chiplet to expose a TSV of the chiplet after releasing the temporary carrier, where during the planarizing, a portion of fillers of the first underfill are planarized. The chiplet provides electrical communication between the semiconductor dies.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor package, comprising:
a chiplet comprising a semiconductor substrate and die connectors disposed over the semiconductor substrate;
a first underfill surrounding the chiplet and comprising first fillers, a portion of the first fillers comprising a substantially planar surface at a first surface of the first underfill; and
a first encapsulant laterally covering the first underfill, the first encapsulant comprising a first surface and a second surface opposite to the first surface, the first surface being substantially leveled with surfaces of the die connectors, and the second surface being substantially leveled with the first surface of the first underfill.

2. The semiconductor package of claim 1, further comprising:
semiconductor dies disposed over and partially overlapping the chiplet, the chiplet providing electrical communication between the semiconductor dies; and
a second underfill surrounding the semiconductor dies, a material of the second underfill being different from that of the first underfill.

3. The semiconductor package of claim 2, wherein the first fillers included in the first underfill are larger than second fillers included in the second underfill.

4. The semiconductor package of claim 2, wherein a first filler loading of the first filler is greater than a second filler loading of second fillers included in the second underfill.

5. The semiconductor package of claim 1, wherein the chiplet further comprises a through substrate via penetrating through the semiconductor substrate (TSV) and electrically coupled to the die connectors, and a surface of the TSV is substantially leveled with the first surface of the first underfill.

6. The semiconductor package of claim 1, wherein a portion of the first encapsulant extends between adjacent two of the die connectors and is in direct contact with a sidewall and a top surface of a dielectric layer of the chiplet.

7. The semiconductor package of claim 1, wherein in a top-down view, the first underfill continuously surrounds a boundary of the chiplet.

8. The semiconductor package of claim 1, wherein the first underfill comprises discrete portions, each of the portions surrounds one of corners of the chiplet in a top-down view.

9. The semiconductor package of claim 1, wherein the first underfill extends between adjacent two of the die connectors, a second surface of the first underfill opposite to the first surface of the first underfill is substantially leveled with the first surface of the first encapsulant.

10. The semiconductor package of claim 9, wherein another portion of the first fillers of the first underfill comprises a substantially planar surface at the second surface of the first underfill.

11. A semiconductor package, comprising:
an interposer comprising:
a chiplet comprising a semiconductor substrate, a TSV penetrating through the semiconductor substrate, and die connectors disposed over the semiconductor substrate and electrically coupled to the TSV;
a first underfill covering at least a portion of a sidewall of the chiplet; and
an encapsulant covering the first underfill, a coefficient of thermal expansion of the first underfill being greater than that of the encapsulant; and
semiconductor dies disposed on the interposer and electrically coupled to the chiplet.

12. The semiconductor package of claim 11, further comprising:
a second underfill disposed over the interposer and covering the semiconductor dies, wherein a filler size of the second underfill is less than that of the first underfill.

13. The semiconductor package of claim 11, further comprising:
a circuit substrate electrically coupled to the semiconductor dies through the interposer, wherein the interposer is disposed between the circuit substrate and the semiconductor dies.

14. The semiconductor package of claim 11, wherein a ratio of a height of the first underfill on the sidewall of the chiplet to a height of the first encapsulant is at least about 0.2, inclusive.

15. A manufacturing method of a semiconductor package, comprising:
forming an interposer comprising:
securing a chiplet to a temporary carrier by using a first underfill;
forming an encapsulant over the temporary carrier to laterally cover the first underfill and the chiplet; and
planarizing a backside of the chiplet to expose a TSV of the chiplet after releasing the temporary carrier, wherein during the planarizing, a portion of fillers of the first underfill are planarized; and
coupling semiconductor dies to the interposer, wherein the chiplet provides electrical communication between the semiconductor dies.

16. The manufacturing method of claim 15, further comprising:
forming a second underfill in a gap between the interposer and the semiconductor dies, wherein a filler size of the second underfill is less than that of the first underfill.

17. The manufacturing method of claim 15, wherein the chiplet comprises die connectors disposed over and electrically coupled to the TSV, and forming the encapsulant comprises:
forming the encapsulant between adjacent two of the die connectors to laterally cover the die connectors.

18. The manufacturing method of claim 15, wherein the chiplet comprises die connectors disposed over and electrically coupled to the TSV, and securing the chiplet to the temporary carrier by using the first underfill comprises:
forming the first underfill between adjacent two of the die connectors to laterally cover the die connectors.

19. The manufacturing method of claim 18, wherein securing the chiplet to the temporary carrier by using the first underfill comprises:
forming the first underfill to continuously surround a bottom edge of the chiplet in a top view.

20. The manufacturing method of claim 15, wherein securing the chiplet to the temporary carrier by using the first underfill comprises:
forming the first underfill at each corner of the chiplet.
